(19) United States
(12) Patent Application Publication
(10) Pub. No.: US 2012/0096944 A1
(43) Pub. Date: Apr. 26, 2012

(54) DEVICE FOR MEASURING PRESSURE, AND METHOD FOR MANUFACTURING SAME

(75) Inventor: Jacques Leclerc, Valence (FR)

(73) Assignee: TRONIC'S MICROSYSTEMS, Crolles (FR)

(21) Appl. No.: 13/379,399

(22) PCT Filed: Jul. 5, 2010
(86) PCT No.: PCT/FR2010/051415

§ 371 Date: Dec. 20, 2011

Related U.S. Application Data
(60) Provisional application No. 61/224,581, filed on Jul. 10, 2009.

(30) Foreign Application Priority Data
Jul. 6, 2009 (FR) 0954667

(51) Int. Cl. G01L 9/12; H01L 21/02

(52) U.S. Cl. 73/718; 438/50; 257/E21.002

(57) ABSTRACT

Device for measuring pressure through the capacitive effect between two electrodes including at least one sensitive electrode spaced apart from and opposite a stationary electrode so as to define a cavity in which a reference pressure (Pref) exists. The device in accordance with the invention further includes a protective housing for insulating at least the stationary electrode from the ambient environment in which the pressure to be measured exists, the housing having at least one solid portion forming a recess for containing at least the stationary electrode, and a thinned portion forming the sensitive electrode.

### CROSS-REFERENCE TO RELATED APPLICATIONS

The present application is a National Stage Application of PCT International Application No. PCT/FR2010/051415 (filed on Jul. 5, 2010), under 35 USC. §371, which claims priority to French Patent Application No. 0954667 (filed on Jul. 6, 2009) and U.S. Provisional Patent Application No. 61/224,581 (filed on Jul. 10, 2009), which are each hereby incorporated by reference in their respective entireties.

### FIELD OF THE INVENTION

The invention relates to the field of MicroElectroMechanical Systems (MEMS), and more specifically, capacitive pressure sensors or devices for measuring pressure by variation of the capacitive effect between two electrodes, and the method for manufacturing same.

### BACKGROUND OF THE INVENTION

Generally speaking, a capacitive pressure sensor includes a flexible membrane and a stationary membrane, separated from each other by a cavity in which a reference pressure, for example a vacuum, exists. The flexible membrane forms or supports a sensitive deformable electrode and the stationary membrane forms or supports a stationary electrode. Under the effect of a pressure difference between a pressure to be measured and the reference pressure, the flexible membrane is deformed either in the direction of the stationary membrane, or by moving away from the stationary membrane. This variation in the distance between these two membranes translates into a variation in the capacity between these two electrodes, and measuring this variation in capacity serves to determine the pressure difference, and therefore the pressure to be measured.

The sensor described above is intended in particular to be implemented in an industrial or biological environment. In order to protect the sensitive and stationary electrodes, generally made of silicon, from any attacks from the ambient environment (industrial or biological), the assembly formed by the sensitive and stationary electrodes is encased in a protective housing guaranteeing that the electrodes can operate in a non-aggressive atmosphere. This housing is generally made from a metal material appropriate to the ambient environment, such as titanium for biocompatible applications or stainless steel for industrial applications. The pressure to be measured is transmitted from the housing to the sensitive electrode by means of a transmission interface generally constituted by pre-degassed oil.

The requirement of not introducing any gas bubbles into the transmission interface, when filling and closing the housing, makes the process for manufacturing this type of sensor particularly difficult and expensive. Furthermore, a leak of degassed oil may be detrimental to measurement accuracy, but may also prove dangerous when used in a biological environment.

### SUMMARY OF THE INVENTION

In this context, the purpose of this invention is to propose a pressure sensor that is free from at least one of the aforementioned limitations. One particular objective of the invention is to propose a less expensive industrial or biocompatible pressure sensor. A further objective of the invention is to eliminate any risk of the degassed oil leaking.

Another object of the invention is a device for measuring pressure through the capacitive effect between two electrodes, including at least one sensitive electrode spaced apart from and opposite a stationary electrode so as to define a cavity in which a reference pressure exists.

The device in accordance with the invention further includes a protective housing for insulating at least the stationary electrode from the ambient environment in which the pressure to be measured exists, said housing having at least one solid portion, forming a recess for containing at least the stationary electrode, and a thinned portion forming the sensitive electrode.

Put another way, the sensitive electrode and the recess form a protective body (or housing) serving to insulate the stationary electrode from the ambient environment. Thus, unlike the prior art, the sensitive electrode is no longer placed inside a protective housing, but is an integral part of the protective housing, and is therefore in direct contact with the ambient environment. The variation in capacity representing a pressure difference between the pressure to be measured and the reference pressure is measured between the stationary electrode and the sensitive electrode. In this solution, The transmission component present in prior art pressure sensors is therefore no longer necessary.

To advantage, the housing is made out of a metal material. For example, the housing may be made out of a material that is adapted to the ambient environment, for example of the biocompatible type, such as titanium, or of the type that is resistant to stress or attack in the industrial environment, such as stainless steel.

In accordance with one embodiment, the device further includes a grid or perforated wall, for protecting the sensitive electrode. The grid or perforated wall serves in particular to protect the sensitive electrode from some undesirable effects such as impacts with objects that have blunt contours capable of damaging the surface of the sensitive electrode, while enabling the ambient environment to be in contact with the sensitive electrode.

Preferably, the protective housing further has an intermediate portion forming a junction between the sensitive electrode and the recess, and having a profile capable of mechanically decoupling the structural variations of the sensitive electrode from those of the recess.

Put another way, this junction acts as a mechanical decoupling means and serves to restrict the undesirable effects due in particular to variations in the structure of the recess, such as thermal expansion, on the structure of the sensitive electrode.

In accordance with one embodiment, the profile of the junction is of decreasing thickness in the direction of the sensitive electrode.

In accordance with another embodiment, the junction profile has a thinned portion placed head to foot with the thinned portion forming the sensitive electrode.

Such profiles serve to limit the stress exerted on the sensitive electrode, such as expansion due to the variation in the ambient temperature for example, thereby preventing impaired measurement.

Advantageously, a sealing frame surrounds the stationary electrode and is spaced apart from the stationary electrode so as to define an interstice accommodating a connection frame, said connection frame providing a mechanical connection and a mechanical decoupling between the stationary electrode and the sealing frame.

Put another way, the connection frame acts as a mechanical decoupling means between the stationary electrode and the sealing frame, and serves in particular to strongly reduce, or even to eliminate all stresses on the stationary electrode, related to variations in the structure of the sealing frame, for example a thermal expansion.

Advantageously, the connection frame surrounds the stationary electrode and has at least one projection secured to the sealing frame, and another projection secured to the stationary electrode.

The connection frame may thus be spaced apart from the stationary electrode and the sealing frame, and may have at least one projection rigidly connected to the sealing frame and another projection rigidly connected to the stationary electrode. For example, the connection frame may have two projections placed opposite to one another and secured to the stationary electrode, and two other projections placed opposite to one another and secured to the sealing frame.

Preferably, the stationary electrode, the connection frame and the sealing frame form a body that has a plane structure placed in the recess. The device may further include a reference electrode insensitive to pressure variations.

In accordance with embodiments of the invention, a method for manufacturing at least one pressure measuring device as specified above, includes at least the following steps: producing at least one stationary electrode by etching in a substrate; producing at least one thinned portion forming a sensitive electrode, on a plate made of material compatible with the ambient environment in which the pressure to be measured exists; sealing, under reference pressure, the plate on the substrate by interposing at least one sealing joint, the sensitive electrode being spaced apart from and opposite the stationary electrode so as to define a cavity the depth of which is defined by the thickness of the sealing joint; and then sealing a part made of material compatible with the ambient environment forming a recess, with the plate, to form a protective housing for insulating at least the stationary electrode from the ambient environment, the housing having at least one solid portion forming the recess, and a thinned portion forming the sensitive electrode.

In accordance with one embodiment, the method further includes producing an intermediate portion forming a junction between the solid portion and the thinned portion, and the profile of which is of decreasing thickness in the direction of the sensitive electrode.

In accordance with another embodiment, the method further includes at least producing an intermediate portion forming a junction between the solid portion and the thinned portion, and the profile of which has a thinned portion placed head to foot with the thinned portion forming the sensitive electrode.

Advantageously, the substrate is constituted by a dielectric layer interposed between two semiconductor layers, and producing the stationary electrode includes at least the steps of: etching in one of the two semiconductor layers to produce at least one sealing frame, a connection frame and the stationary electrode, the sealing frame surrounding the stationary electrode and being spaced apart from the stationary electrode so as to define an interstice accommodating the connection frame, the connection frame surrounding the stationary electrode and having at least one projection secured to the sealing frame and another projection secured to the stationary electrode; and then removing a portion of the dielectric layer opposite the stationary electrode, the connection frame and a portion of the sealing frame.

Additionally, the coefficient of expansion of the material in which the sensitive electrode is produced, for example, titanium or stainless steel may be higher by a factor of between 4 to 6 than that of the material out of which the stationary electrode is produced, for example, silicon (the coefficient of expansion of silicon is about 2.6·10⁻⁶/° C.). The thermo-compression bonding of the housing to the sealing frame proves difficult. Consequently, it is then necessary to produce a specific joint in order to take this expansion difference into account, and to ensure the sealing frame is bonded to the housing.

In accordance with embodiments of the invention, preferably, sealing further includes steps of: producing a first metal layer on an internal portion of the solid portion intended to be opposite the sealing frame; producing a second metal layer on a portion of the sealing frame; and then sealing the first and second metal layers by thermo-compression.

The manufacturing method described above applies to an individualised pressure measurement device manufacture, but also to a collective manufacture, i.e., a manufacture of a plurality of the pressure measurement devices presented above. For example, a method for manufacturing a plurality of pressure measurement devices as specified above includes at least the following steps: producing a plurality of stationary electrodes by etching a substrate; producing a plurality of thinned portions forming sensitive electrodes on a plate made of material compatible with the ambient environment in which the pressure to be measured exists; sealing, under reference pressure, the plate on the substrate by interposing a plurality of sealing joints so as to form a plurality of cavities, each of the cavities being defined by one of the sensitive electrodes spaced apart from and opposite one of the stationary electrodes, and having a depth defined by the thickness of the associated sealing joint; forming a plurality of elementary modules by cutting between two adjacent sealing joints, each elementary module including at least one of the cavities; and then for each elementary module, sealing with a recess made of material compatible with the ambient environment, to form a protective housing for insulating at least the stationary electrode of the elementary module from the ambient environment, the housing having at least one solid portion forming a recess and a thinned portion forming a sensitive electrode.

In accordance with one embodiment, the method further includes, for each sensitive electrode, producing an intermediate portion on the plate, intended to form a junction between the recess and the sensitive electrode, and the profile of which is of decreasing thickness in the direction of the sensitive electrode.

In accordance with another embodiment, the method further includes at least, for each sensitive electrode, producing an intermediate portion on the plate, intended to form a junction between the recess and the sensitive electrode, and the profile of which has a thinned portion arranged head to foot with the thinned part forming the sensitive electrode.

Advantageously, the substrate is constituted by a dielectric layer interposed between two semiconductor layers, and producing the stationary electrode includes at least steps of: etching in one of the two semiconductor layers in order to produce, for each of the stationary electrodes, a sealing frame surrounding at a distance the stationary electrode so as to define an interstice accommodating a connection frame having at least one projection secured to the sealing frame and another projection secured to the stationary electrode; and then removing portions of the dielectric layer opposite at least the stationary electrodes and the connection frames.

### BRIEF DESCRIPTION OF THE DRAWINGS

The way in which the invention may be implemented, together with the resulting advantages, will become clearer from the description of the following embodiments, supported by the appended drawings.

FIG. 1 is a diagrammatic cross-section view of a capacitive pressure sensor in accordance with one embodiment of the invention.

FIG. 2 is a diagrammatic cross-section view of a capacitive pressure sensor in accordance with another embodiment.

FIG. 3 is a diagrammatic perspective view of the substrate in which the stationary electrode is produced in accordance with one embodiment of the invention.

FIGS. 4 to 14 illustrate some steps in the method for manufacturing the pressure sensor in accordance with one embodiment of the invention.

FIGS. 15 to 17 illustrate some steps in the method for the collective manufacture of a plurality of pressure sensors in accordance with one embodiment of the invention.

### DETAILED DESCRIPTION OF EMBODIMENTS

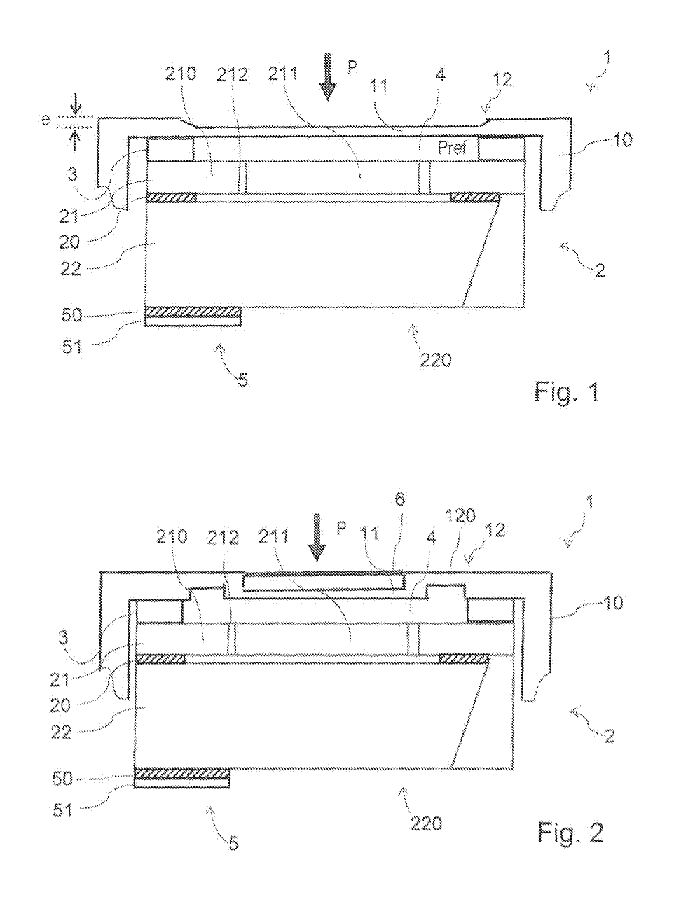

With reference to FIGS. 1 and 2, the pressure measurement device includes a protective housing 1 (only one portion of which has been illustrated herein) which may be made out of a metal material compatible with the ambient environment in which the pressure to be measured P exists, such as titanium or stainless steel, for example. This housing 1 has a solid portion forming a recess 10 for accommodating a stationary electrode 211, a thinned portion forming a sensitive electrode 11, and an intermediate portion forming a junction 12 between the sensitive electrode 11 and the recess 10. The sensitive electrode 11 is, therefore, made directly out of the material in which the protective housing 1 is made, and is therefore directly in contact with the ambient environment. The recess 10, the sensitive electrode 11 and the junction 12 thus form a structure capable of protecting the stationary electrode 211 from attack from the ambient environment.

Additionally, as illustrated in FIG. 2, a protective grid 6 or perforated wall may be placed opposite the sensitive electrode 11 to limit undesirable effects, such as impacts with objects that have blunt contours that might damage the surface of the sensitive electrode 11.

In order to insulate the sensitive electrode 11 from any structural variations in the recess 10, for example, a thermal expansion due to a sealing process which may cause significant variations in temperature, the junction 12 may have a profile serving to mechanically decouple the structural variations of the sensitive electrode 11 from those of the recess 10. For example, the profile of this junction 12 may have a thickness e decreasing in the direction of the sensitive electrode 11, as illustrated in FIG. 1. The profile of the junction 12 may also have a thinned portion 120 arranged head to foot with the thinned portion forming the sensitive electrode 11, as illustrated in FIG. 2. These profile examples serve in particular to limit the thermal stresses sustained by the recess 10 on the sensitive electrode 11.

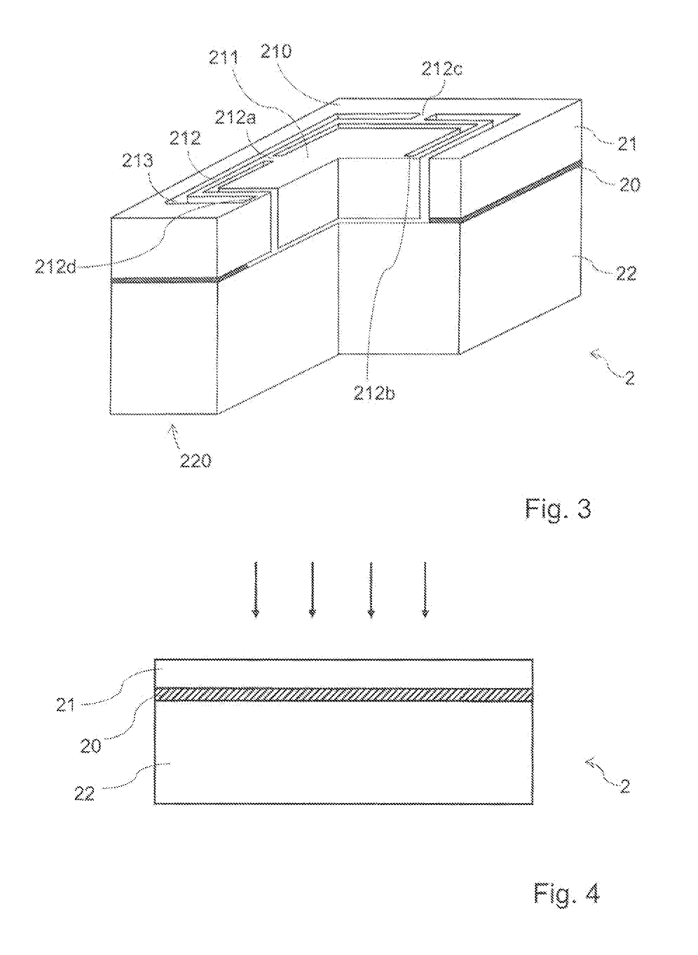

The recess 10 contains a substrate 2, of the Silicon-On-Insulator (SOI) type for example, constituted by a dielectric layer 20 composed of oxide, for example, interposed between two semiconductor layers 21, 22, composed of, for example, silicon. In one of the two silicon layers 21 are produced the stationary electrode 211, a sealing frame 210 and a connection frame 212 connecting the stationary electrode 211 to the sealing frame 210. The sealing frame 210 surrounds the stationary electrode 211 and is spaced apart from the stationary electrode 211 so as to define an interstice 213 accommodating the connection frame 212, as illustrated in FIG. 3.

Likewise, in order to insulate the stationary electrode 211 from any structural variations in the sealing frame 210, and in particular a thermal expansion due to the sealing method, the connection frame 212 is produced so as to have a profile serving to mechanically decouple the structural variations of the stationary electrode 211 from those of the sealing frame 210. For example, as shown in FIG. 3, the connection frame 212 surrounds the stationary electrode 211, and is spaced apart from the stationary electrode 211 and from the sealing frame 210. The connection frame has two projections 212, 212b placed opposite one another and secured to the stationary electrode 211, and two other projections 212c, 212d placed opposite one another and secured to the sealing frame 210. The particular advantage of this profile is that it secures the stationary electrode 211 to the sealing frame 210, while limiting the thermal stresses sustained by the sealing frame 210 on the stationary electrode 211. The stationary electrode 211, the connection frame 212 and the sealing frame 211 thus form a body having a plane structure.

The substrate 2 is secured to the housing 1 by means of a sealing joint 3, so as to space the sensitive electrode 11 apart from and opposite the stationary electrode 211, so as to define a cavity 4 the depth of which is defined by the thickness of the sealing joint 3. The cavity 4 is under reference pressure P_{ref}, for example, a vacuum, and the variation in capacity, representing a pressure difference between the pressure to be measured and the reference pressure, is measured between the sensitive electrode 11 and the stationary electrode 211. Since the sensitive electrode 11 is directly in contact with the ambient environment, no transmission component is therefore required, unlike in the prior art.

On the free face 220 of the other semiconductor layer 22, it is also possible to place a reference electrode 51 by means of another dielectric layer 50, oxide for example, in order to make a reference capacity 5 insensitive to any pressure variation. It is also possible to place on this same free face 220 electrical contact zones and means for processing the signals of the sensor.

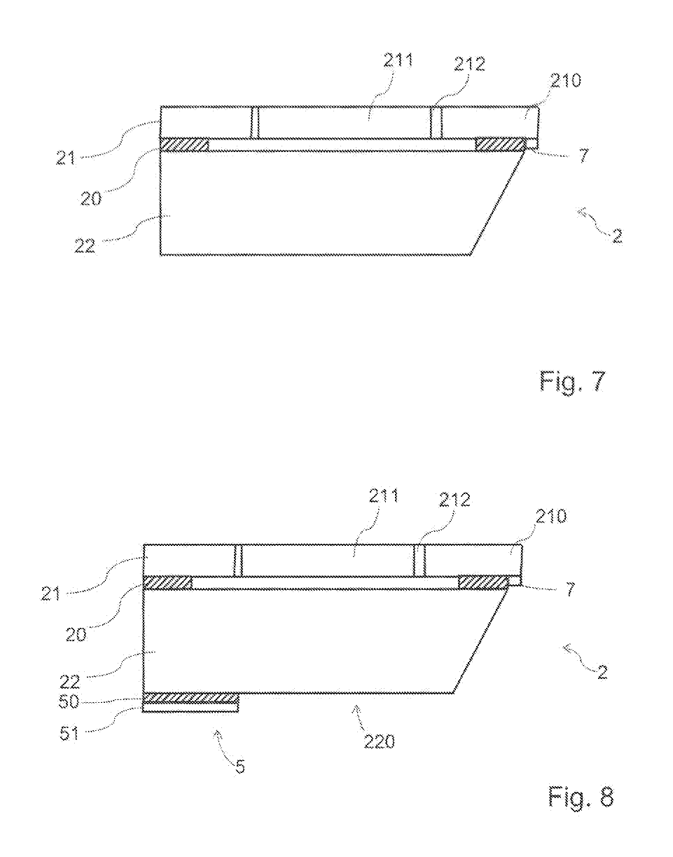

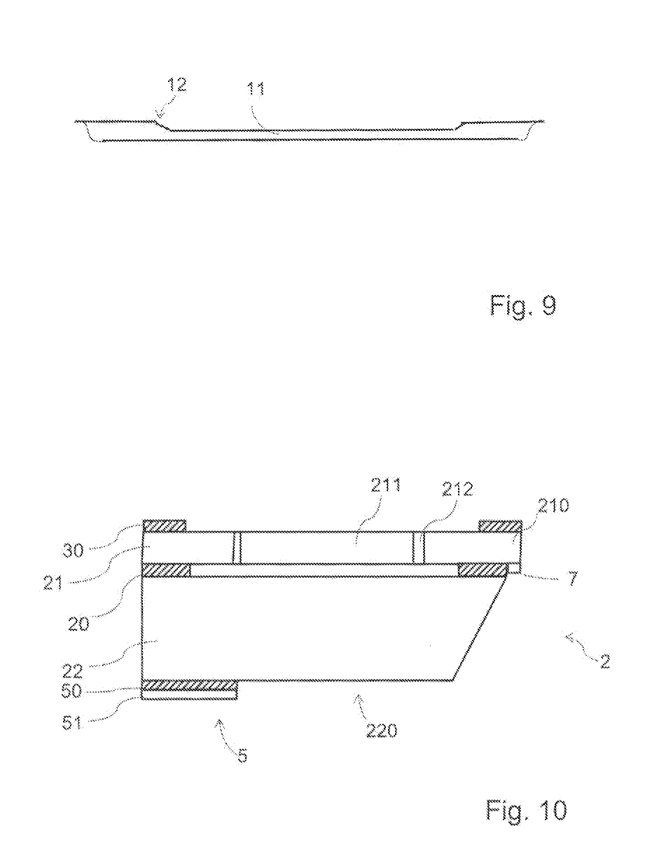

The method for manufacturing such a pressure sensor in accordance with one embodiment includes in particular: producing the stationary electrode 211 (FIGS. 4 to 6); producing the reference capacity 5 and connection means (FIGS. 7 and 8); producing the sensitive electrode 11 (FIG. 9); producing the sealing joint (FIGS. 10 to 13); and producing the protective housing 14).

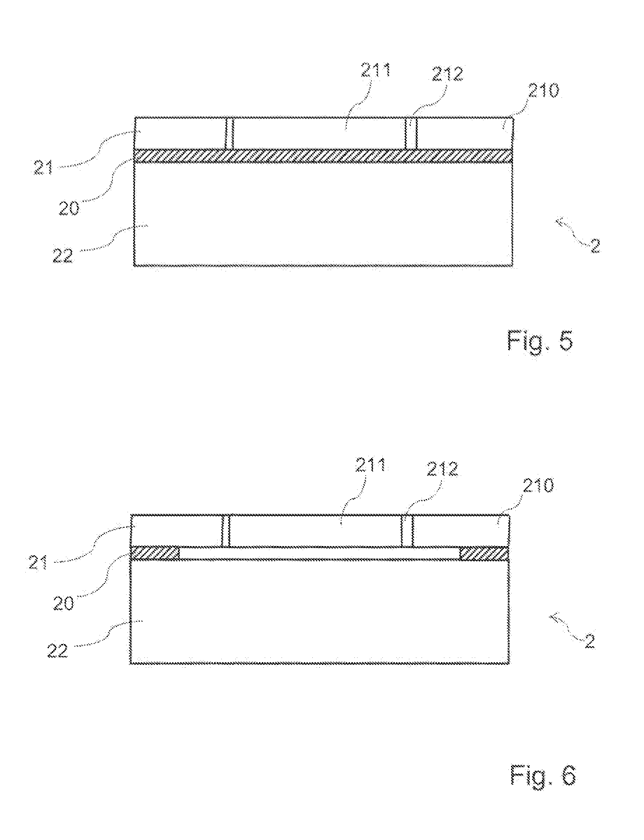

As illustrated in FIGS. 4 to 6, producing the stationary electrode 211 includes in particular etching (FIGS. 4 and 5) on one of the two semiconductor layers 21 of the wafer so as to form the stationary electrode 211, the connection frame 212 and the sealing frame 210 as specified previously. The stationary electrode 211 is released by removing (FIG. 6) a portion of the dielectric layer 20 located opposite the stationary electrode 211, the connection frame 212 and a portion of the sealing frame 210.

As illustrated in FIG. 7, at this stage in the method, it is possible to make provision for an access through the other semiconductor layer 22 and the dielectric layer 20 in anticipation of an electrical contact 7 for the stationary electrode 211. As illustrated in FIG. 8, it is also possible to produce the reference capacity 5 by placing the other dielectric layer 50 on a portion of the free surface 220 of the other semiconductor layer 22, then by placing a reference electrode 51 on the other dielectric layer 50, in such a way that the reference electrode 51 remains insensitive to any variation in pressure.

As illustrated in FIG. 9, a material compatible with the ambient environment, for example, titanium or stainless steel, is formed in order to produce the recess 210, the sensitive electrode 211 and the junction 212 as specified previously, and thereby to form the protective housing 1. Additionally, the protection for the sensitive electrode 11, such as a grid or perforated wall placed opposite the sensitive electrode, may also be implemented at this stage.

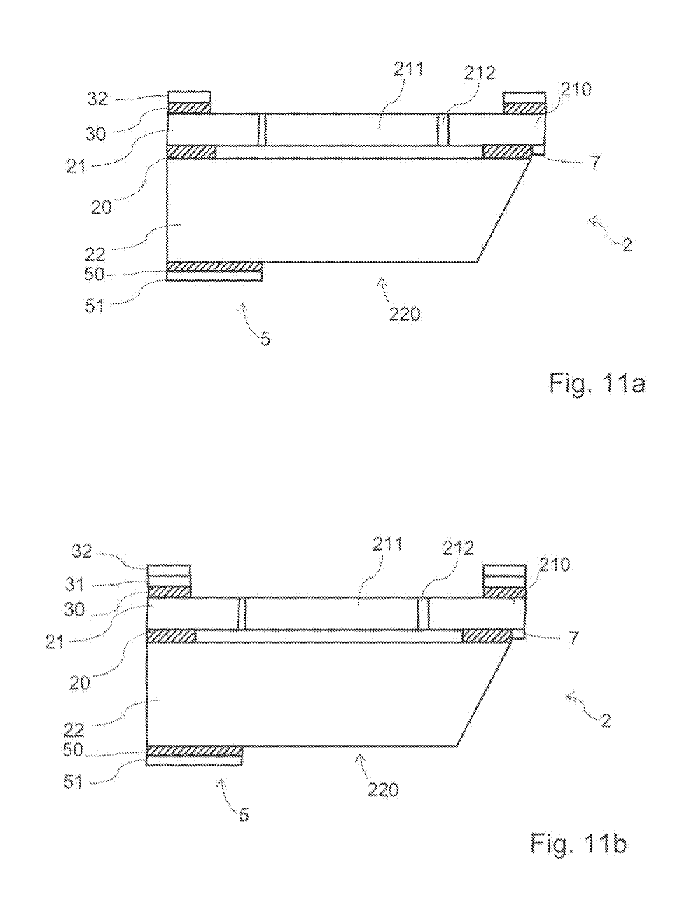

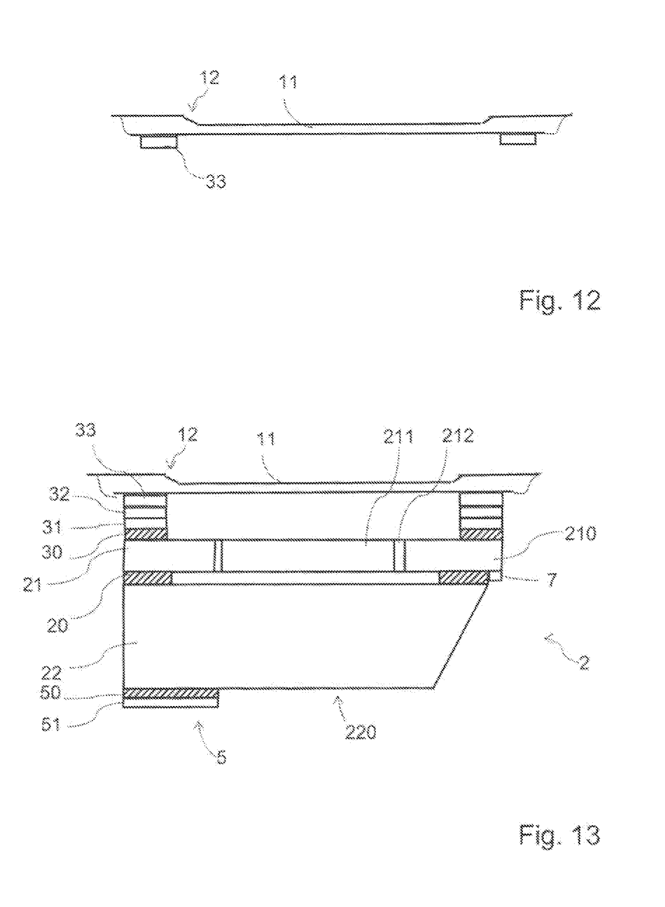

As illustrated in FIGS. 10 to 13, given a significant difference between the coefficients of expansion of silicon and titanium or stainless steel, producing the sealing joint 3 may in particular include: depositing an intermediate oxide layer 30 on a portion of the sealing frame 210 (FIG. 10); depositing a first metal layer 33, such as gold, for example, on a portion of the housing 1 intended to be opposite the sealing frame 21 (FIG. 12); depositing an intermediate metal layer 31 such as titanium (FIG. 11b) on the intermediate oxide layer 30, and then a second metal layer 32 such as gold on the intermediate metal layer 31; or directly depositing the second metal layer 32 (FIG. 11a) on the intermediate oxide layer 30; and then sealing by thermo-compression (FIG. 13) the first and second metal layers 33, 32, under reference pressure P_{ref}, so that the sensitive electrode 11 is spaced apart from and opposite the stationary electrode 211 so as to define the cavity 4 the depth of which is defined by the thickness of the sealing joint 3 made. Obviously, other types of lower temperature sealing are conceivable. However, in the particular case of titanium, a direct titanium on silicon oxide sealing may be used to advantage as a replacement for thermo-compression.

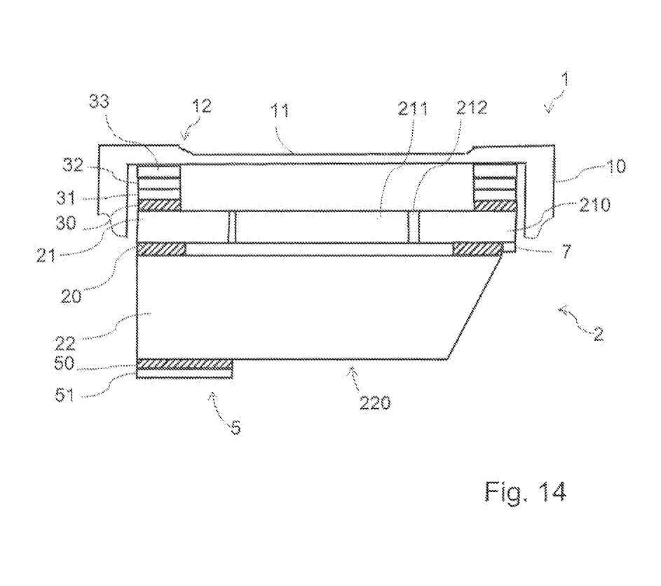

As illustrated in FIG. 14, a recess 10 is then welded to the plate to form the protective housing 1 in which is placed the stationary electrode 211 which is thus insulated from the ambient environment.

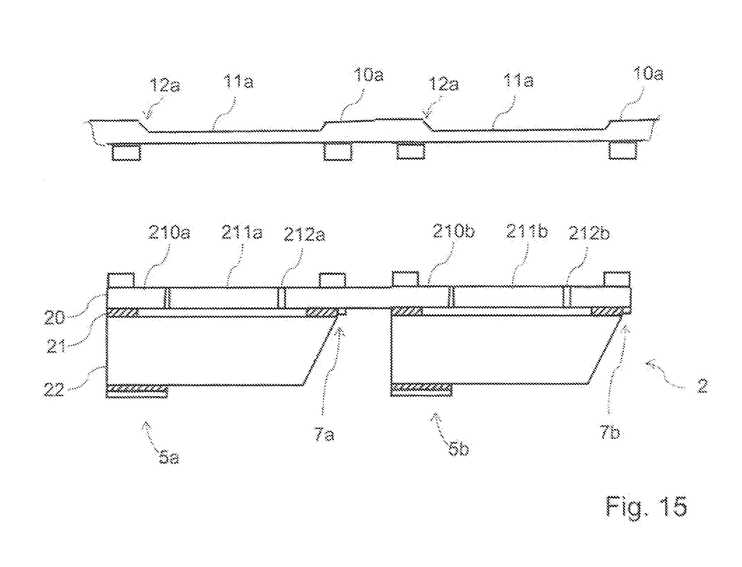

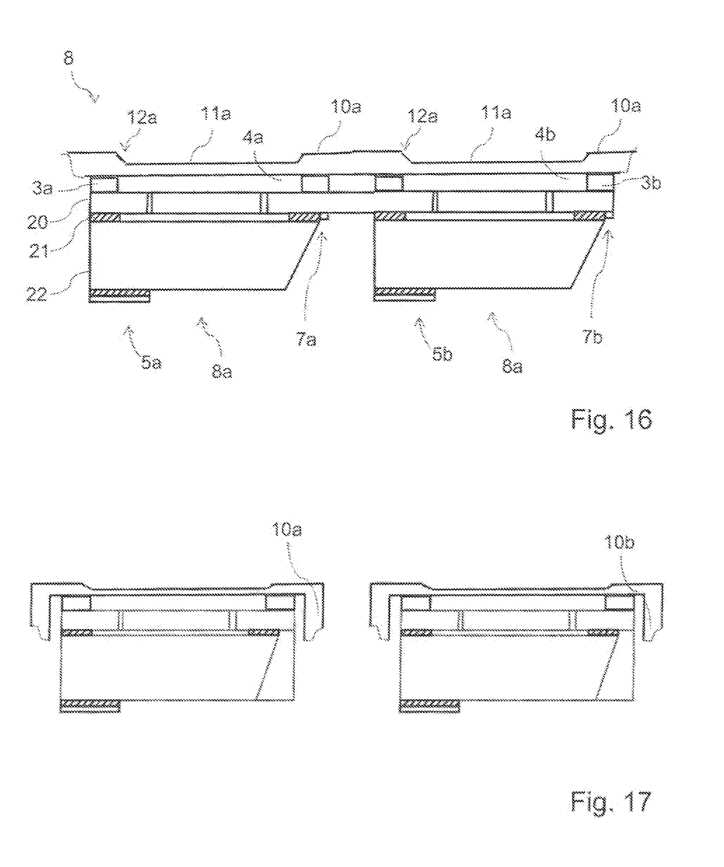

As illustrated in FIGS. 15 to 17, the manufacturing method disclosed above may also be applied to a collective manufacture of a plurality of pressure measurement devices, which may include producing a structure 8 of a plurality of elementary modules 8a, 8b, each elementary module 8a, 8b including in particular a cavity 4a, 4h defined by a sensitive electrode 11a, 11b, a stationary electrode 211a, 211b and a sealing joint 3a, 3b the thickness of which defines the depth of the cavity 4a, 4b. The structure 8 may be made from a plate made of material compatible with the ambient environment and a substrate as specified above. The plate is formed (FIG. 15) so as to obtain a plurality of sensitive electrodes 11a, 11b and a plurality of junctions 12a, 12b as specified previously. As illustrated in FIG. 15, the substrate is also etched in accordance with the principle for producing a stationary electrode disclosed above, in order to obtain a plurality of sealing frames 210a, 210b, connection frames 212a, 212b and stationary electrodes 211a, 211b. As illustrated in FIG. 16, the plate is sealed to the substrate by interposing a plurality of sealing joints 3a, 3b in order to produce a plurality of cavities 4a, 4b as specified previously and thereby to obtain a plurality of elementary modules 8a, 8b. As illustrated in FIG. 17, the structure is then cut up to disconnect the elementary modules 8a, 8b from one another. Lastly, for each elementary module 8a, 8b, a protective housing is produced having a solid portion forming a recess 10a, 10b, an intermediate portion forming a junction 12a, 12b and a thinned portion forming a sensitive electrode 11a, 11b. A plurality of pressure sensors is thus obtained which have the particularity of having a sensitive electrode included in the protective housing in contact with the ambient environment. Obviously, for each elementary module, it is possible to make provision for a protective grid and a reference electrode as specified previously.

It is clear from what has already been stated that the inventive pressure sensor is free from transmission interface, and in particular from degassed oil, and may in particular be employed in respect of applications that require inexpensive biocompatible pressure sensors. For example, the inventive pressure sensor may in particular be easily integrated into a catheter, but may also be employed in respect of industrial applications and in particular those related to aeronautics.

Although embodiments have been described herein, it should be understood that numerous other modifications and embodiments can be devised by those skilled in the art that will tall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1-18. (canceled)

19. A device for measuring pressure through a capacitive effect between two electrodes, the device comprising:
a stationary electrode;
at least one sensitive electrode having a first thinned portion, the at least one sensitive electrode being spaced apart from and opposite the stationary electrode so as to define a cavity in which a reference pressure exists;
a housing configured to insulate at least the stationary electrode from the ambient environment in which the pressure to be measured exists, the housing having at least one solid portion forming a recess configured to contain at least the stationary electrode and the first thinned portion.

20. The device of claim 19, wherein the housing is composed of a metal material.

21. The device of claim 19, further comprising one of a grid and a perforated wall each configured to protect the sensitive electrode.

22. The device of claim 21, wherein the housing includes an intermediate portion forming a junction between the sensitive electrode and the recess, and having a profile configured to mechanically decouple the sensitive electrode from the recess.

23. The device of claim 22, wherein the profile of the junction has a thickness decreasing in a direction of the sensitive electrode.

24. The device of claim 22, wherein the profile of the junction has a second thinned portion its entire length of which is placed with the first thinned portion of the sensitive electrode.

25. The device of claim 19, further comprising a sealing frame surrounds the stationary electrode and is spaced apart from the stationary electrode so as to define an interstice configured to accommodate a connection frame, wherein the connection frame is configured to provide a mechanical connection and a mechanical decoupling between the stationary electrode and the sealing frame.

26. The device of claim 25, wherein the connection frame surrounds the stationary electrode and has at least one first projection secured to the sealing frame and a second projection secured to the stationary electrode.

27. The device of claim 19, further comprising a reference electrode which is configured to be insensitive to variations in pressure.

28. A method for manufacturing at least one pressure measuring device for measuring pressure through a capacitive effect between two electrodes, the method comprising:
producing at least one stationary electrode by etching a substrate;
producing at least one thinned portion forming a sensitive electrode on a plate composed of material compatible with the ambient environment in which the pressure to be measured exists;
sealing under a reference pressure the plate on the substrate by interposing at least one sealing joint, such that the sensitive electrode is spaced apart from and opposite the stationary electrode so as to define a cavity the depth of which is defined by the thickness of the at least one sealing joint; and then
sealing with the plate a part made of material compatible with the ambient environment forming a recess, to form a housing configured to insulate at least the stationary electrode from the ambient environment, the housing having at least one solid portion forming the recess, and the thinned portion which forms the sensitive electrode.

29. The method of claim 28, further comprising producing an intermediate portion forming a junction between the solid portion and the thinned portion, the intermediate portion having a profile with a thickness which decreases in a direction of the sensitive electrode.

30. The method of claim 28, further comprising producing an intermediate portion forming a junction between the solid portion and the thinned portion, the intermediate portion having a profile with at least one thinned portion its entire length of which is placed with the thinned portion which forms the sensitive electrode.

31. The method of claim 28, wherein the comprises a dielectric layer interposed between two semiconductor layers.

32. The method of claim 31, wherein producing the stationary electrode comprises:
etching one of the two semiconductor layers to produce at least one sealing frame, a connection frame and the stationary electrode, the sealing frame being configured to be spaced apart from and surround the stationary electrode so as to define an interstice configured to accommodate the connection frame, the connection frame being configured to surround the stationary electrode and having at least one first projection secured to the sealing frame and a second projection secured to the stationary electrode; and then
removing a portion of the dielectric layer opposite the stationary electrode, the connection frame and a portion of the sealing frame.

33. The method of claim 32, wherein the sealing further comprises:
producing a first metal layer on an internal portion of the solid portion forming the recess intended to be opposite the sealing frame;
producing a second metal layer on a portion of the sealing frame; and then
sealing the first and second metal layers by thereto-compression.

34. The method of claim 28, further comprising:
producing a plurality of stationary electrodes by etching a substrate;
producing a plurality of thinned portions configured to form sensitive electrodes on a plate composed of material compatible with the ambient environment in which the pressure to be measured exists;
sealing, under a reference pressure the plate on the substrate by interposing a plurality of sealing joints so as to form a plurality of cavities, each of the cavities being defined by one of the sensitive electrodes spaced apart from and opposite one of the stationary electrodes and having a depth defined by the thickness of the associated sealing joint;
forming a plurality of elementary modules by cutting between two adjacent sealing joints, each elementary module including at least one of the cavities;
for each elementary module, sealing with a recess composed of material compatible with the ambient environment, to thereby form a housing configured to insulate at least the stationary electrode of the elementary module from the ambient environment, the housing having at least one solid portion forming a recess and a thinned portion forming the sensitive electrode.

35. The method of claim 34, further comprising:
for each sensitive electrode, producing an intermediate portion on the plate to form a junction between the recess and the sensitive electrode, the profile of which has a thickness which decreases in a direction of the sensitive electrode.

36. The method of claim 35, wherein:
the substrate comprises a dielectric layer interposed between two semiconductor layers; and
producing the stationary electrode comprises:
etching in one of the two semiconductor layers in order to produce, for each of the stationary electrodes, a sealing frame surrounding at a distance the stationary electrode so as to define an interstice configured to accommodate a connection frame having at least one projection secured to the sealing frame and another projection secured to the stationary electrode; and then
removing portions of the dielectric layer opposite at least the stationary electrodes and the connection frames.

37. The method of claim 34, further comprising:
for each sensitive electrode, producing an intermediate portion on the plate to form a junction between the recess and the sensitive electrode, the profile of which has at least one thinned portion its entire length of which is placed with the thinned portion which forms the sensitive electrode.

38. The method of claim 36, wherein:
the substrate comprises a dielectric layer interposed between two semiconductor layers; and
producing the stationary electrode comprises:
etching in one of the two semiconductor layers in order to produce, for each of the stationary electrodes, a sealing frame surrounding at a distance the stationary electrode so as to define an interstice configured to accommodate a connection frame having at least one projection secured to the sealing frame and another projection secured to the stationary electrode; and then
removing portions of the dielectric layer opposite at least the stationary electrodes and the connection frames.
